(19) United States
(12) Patent Application Publication
(10) Pub. No.: US 2016/0343884 A1
(43) Pub. Date: Nov. 24, 2016

(54) CHARGE STABILIZED DIELECTRIC FILM FOR ELECTRONIC DEVICES

(71) Applicant: ISIS INNOVATION LIMITED, Oxford, Oxfordshire (GB)

(72) Inventors: Peter WILSHAW, Oxford, Oxfordshire (GB); Ruy Sebastian BONILLA OSORIO, Oxford, Oxfordshire (GB)

(73) Assignee: ISIS INNOVATION LIMITED, Oxford, Oxfordshire (GB)

(21) Appl. No.: 15/106,630

(22) PCT Filed: Dec. 19, 2014
(86) PCT No.: PCT/GB2014/053798

§ 371 Date: Jun. 20, 2016

(30) Foreign Application Priority Data
Dec. 20, 2013 (GB) 1322739.2

(51) Int. Cl. H01L 31/0216; B81B 3/00; B81C 1/00; H01L 31/068; H01L 31/18

(52) U.S. Cl. CPC H01L 31/02168; H01L 31/0682; H01L 31/02161; H01L 31/18; B81C 1/00698; B81B 3/0086

(57) ABSTRACT

Methods of manufacturing a substrate unit that achieve improved levels of efficiency and/or longevity are disclosed. The substrate units may be used for example in solar cells, semiconductor detectors or electrostatic actuators, sensors, harvesters or other electro-mechanical devices. Disclosed methods include the steps of generating, or redistributing into the bulk of the dielectric film, a region of net charge in the dielectric film while the dielectric film is at a temperature greater than 150° C.

The present invention relates to the manufacture of substrate units for electronic devices that have a dielectric film formed on a substrate, for example a semiconducting substrate. The invention may improve the efficiency and/or longevity of operation for example. The substrate units may be used for example in solar cells, semiconductor detectors or electrostatic actuators, sensors, harvesters or other electro-mechanical devices.

Prior art solar cells and semiconductor detectors are known that comprise a substrate base layer (formed from silicon for example) with a dielectric film on top. The dielectric film may be configured to provide a variety of functions. For example, the dielectric film may have anti-reflection properties to maximize the light absorbed into the semiconductor. The dielectric film may act as a passivation layer to protect the semiconductor from impurities. It is also known to adapt the dielectric film, for example by controlling the deposition and material parameters, so that it reduces carrier recombination at the interface between the film and the base layer. Reducing carrier recombination improves the efficiency of the solar cell or detector. However, it has proven difficult to achieve this at the level required to give optimum cell efficiency. Furthermore, selecting the properties of the dielectric layer to reduce carrier recombination may restrict the range of optical properties that are available, leading to a reduction in the effectiveness of the dielectric layer as an anti-reflection coating. It is also known that mere deposition of charge on the dielectric surface will drive carriers away from the interface, but this effect is temporary and does not therefore provide stable reduction of carrier recombination.

Semiconductor sensors are known in which a semiconducting substrate is treated so as to form a thin layer of very highly doped semiconductor material near the surface of the semiconductor. This layer causes energy band bending which generates an electric field within the semiconductor. The electric field acts to passivate an interface between the semiconductor and anti-reflective dielectric layers in a dielectric film formed on the semiconductor substrate. However, carrier recombination processes arising because of the thin layer of very highly doped semiconductor material itself reduces carrier lifetimes and reduces the performance of the sensors.

Electrostatic actuators are known in which an actuatable member (e.g. a member that can be deformed or displaced when a force is applied to the member or to a part of the member) is charged and an electromagnetic field is selectively used to apply a force to the member via the charge. Dissipation of the charge over time can reduce the operational lifetime of the actuator and/or cause general unreliability or low manufacturing yield.

It is an object of the present invention to provide methods and apparatus for manufacturing substrate units for electronic devices that are more efficient than prior art approaches and/or which result in an electronic device that is more reliable, enduring and/or efficient.

According to an aspect of the invention, there is provided a method of manufacturing a substrate unit for an electronic device comprising a dielectric film on a substrate, the method comprising: generating, or redistributing into the bulk of the dielectric film, a region of net charge in the dielectric film while the dielectric film is at a temperature greater than 150° C.

Thus, a region of net charge is formed within the bulk of the dielectric layer, which has the effect of stably producing a localized electric field that penetrates into the substrate and forces charge carriers present in the substrate to move further away from the interface between the dielectric film and the substrate. By reducing the concentration of charge carriers in the region near the interface, the number of charge carriers available for participation in recombination processes is reduced, thus reducing the extent of carrier recombination and improving the efficiency of the substrate unit as part of an electronic device such as a solar cell or detector.

The region of net charge can be generated for example by generating a surplus of ions of a given charge in the dielectric (i.e. more positive ions than negative ions or more negative ions than positive ions), or by separating charges already present in the dielectric to produce a dipole which is stable at operating temperatures, or a mixture of both. The effect of the dipole is to generate a field at the surface of the substrate in the same way as if there had just been a surplus of single sign charges.

Carrying out the generation of the region of net charge at an elevated temperature provides the necessary mobility in the film (e.g. to allow migration of charge within the film or the rearrangement of charged defects) for the region of net charge to be generated or redistributed into the bulk effectively. When the dielectric layer is subsequently cooled, the charged ions or defects become highly immobile and the regions of net charge are effectively “frozen” into the dielectric film. This process produces a dielectric film with regions of net charge that will persist over an extended period of time, typically many months or even years. Thus, efficiencies associated with reduced carrier recombination will persist for extended periods of time. In the case of an electrostatic actuator, the time for which a given net charge can be maintained is extended, thus extending operational lifetime and reliability.

Thus, the inventors have found a way of introducing a region of net charge into a dielectric film that is stable over time. This result is in marked contrast to what is achieved by merely depositing charge on a surface of a dielectric at room temperature. In this case the charge is unstable because it can leak away or be compensated by the accumulation of charged molecules (ions) such as those derived from any water present. In an extreme case the charge can be wiped or washed off. The inventors have overcome this problem by introducing the regions of net charge into the bulk of the dielectric (the charges may in fact migrate all the way to the interface between the substrate and the dielectric film). At device operating temperatures these ions are effectively immobile and, furthermore, because they are buried in the dielectric cannot be washed or wiped off, cannot leak away and are less susceptible to compensation by the accumulation of charges of the opposite sign on the dielectric surface.

In an embodiment, the substrate comprises a semiconductor, such as silicon.

In an embodiment, the formation of the dielectric film is carried out at elevated temperatures, including temperatures greater than 150° C. The generation or redistribution into the bulk of the regions of net charge within the dielectric film can therefore advantageously be carried out during or shortly after the formation of the dielectric film, which makes use of the high processing temperatures that have been generated already for forming the dielectric film, and thereby avoids or reduces the need to reheat the substrate unit at a subsequent time. The method of the present invention can thus be incorporated into existing manufacturing facilities with a minimum of disruption in processing efficiency.

The mechanism for reducing carrier recombination at the interface between the substrate and the dielectric film is valid for a relatively wide range of dielectric film materials. Any material having a moderate chemical passivation characteristic and reasonable charge retention properties would work. Accordingly, there remains a wide scope for optimizing the optical properties of the dielectric film, for example to increase the degree of anti-reflection. For example, the approach of the present embodiment allows dielectric films such as titanium oxide, which have excellent anti-reflective properties but relatively poor electrical properties (in the sense of acting to reduce carrier recombination at the interface between the dielectric film and the substrate), to be used while maintaining a low level of carrier recombination. In this way, it is possible to increase the efficiency of the electronic devices in which the substrate unit is used to higher levels than prior art devices.

In an embodiment, an external electric field is applied which causes one or more of defects, impurities and ions in or on the dielectric film to move (drift) or rearrange, thereby generating or redistributing the region of charge. The inventors have found that for many types of defect, impurity or ion likely to cause a stable region of charge to be generated, establishment of the region of net charge without an external electric field can be a relatively slow process (typically taking about an hour or more for configurations based on in-diffusion of metals deposited on the surface of the dielectric, for example). The inventors have found that with the external electric field defects, impurities or ions can be introduced much more quickly, typically allowing charge concentrations which achieve significant passivation to be achieved within a few minutes (e.g. within 1 or 2 minutes). The use of an externally applied electric field allows impurities or ions which do not move very easily through the material of the film (e.g. relatively large anions, cations, metallic particles/ions or metalloids) to be driven through the film in a reasonable period of time. After cooling of the film to room temperature the region of net charge produced by such impurities or ions may be more stable than where impurities or ions which move more easily through the film (e.g. smaller anions, cations, metallic particles/ions or metalloids) are used, resulting in greater longevity of the substrate unit.

In an embodiment, an external electric field is applied which forces ions of opposite sign to move in opposite directions to each other. In an example of an embodiment of this type the electric field is directed so as to drive cations into the bulk of the film, away from the surface and towards the interface between the film and the substrate. As mentioned above, the electric field causes the ions to move through the film more quickly than would be possible using diffusion only.

In an embodiment, impurities or ions are applied to the dielectric film at a concentration which is such as to reduce the transmittance of the dielectric film by less than 5%, optionally less than 1%, optionally less than 0.1%. For example, in an embodiment the impurities or ions are applied at three times a monolayer concentration or less, optionally at a monolayer concentration or less, optionally at a sub-monolayer concentration. For example, a concentration of impurity/ion particles of the order of 1 particle to 100 molecules of the dielectric film may be used. The inventors have recognised that even such low concentrations of impurity/ion particles can be adequate to achieve high levels of passivation. Where the substrate unit needs to be transparent (e.g. in solar cells) this approach facilitates manufacture, relative to alternative approaches in which thicker layer of impurities or ions are used, because it is no longer necessary to incorporate an extra step of removing the layer of impurities or ions after the required region of net charge has been generated in the dielectric film by diffusion and/or drift of the impurities or ions. The impurities or ions applied at the concentration which is such as to reduce the transmittance of the dielectric film by less than 5%, optionally less than 1%, optionally less than 0.1% may be moved into the bulk by diffusion only, without an applied electric field, or by a combination of diffusion and drift (driven by an applied electric field). The combination of diffusion and drift will normally be substantially quicker and therefore desirable. In alternative embodiments a relatively thick layer of impurities/ions (typically greater than 5 nm) may be applied to the dielectric to act as the source of charged species in the dielectric. In an embodiment the thick layer is sufficiently opaque that it would normally have to be removed for the device using the substrate unit (e.g. solar cell) to be fully operational. However, the inventors have found that even in this situation it can be possible to avoid the additional removal step in certain situations by alternative processing. For example, in the case of a layer of Al the inventors have found that it is possible to oxidise the Al layer (e.g. right through its thickness) to produce a transparent layer of Al₂O₃. The inventors have found that this can be achieved for example by oxidation of Al layers 13 nm or thinner at temperatures of 400 C and above.

In an embodiment, the method comprises applying (e.g. depositing) impurities or ions onto the dielectric before the dielectric is raised above 150° C. The impurities or ions may be applied for example at room temperature. The subsequent step of annealing the dielectric at a temperature above 150° C. then allows movement of the impurities or ions and the associated generation or redistribution of the region of net charge in the dielectric. In other embodiments the impurities or ions are applied while the dielectric is already above 150° C. In the case where positive and negative ions are applied equally, the region of net charge may only develop when the ions are allowed to move, for example during the annealing at high temperature (with or without an electric field). In this case the region of net charge is “generated”. In the case where ions are applied unevenly (e.g. more positive than negative or more negative than positive), or where ions of one polarity are lost at the surface to a greater extent than ions of the other polarity, a region of net charge may be present at the surface of the dielectric film before the annealing step. In this case, the movement of the ions caused by the annealing (with or without external electric field) constitutes a “redistribution” of the region of the net charge. The region of net charge may also be “generated” by movement of impurities which are not strictly ions but which nevertheless disrupt the dielectric in such a way as to cause a region of net charge to develop (and an associated electric field to penetrate into the substrate). The disruption may cause charged defects to develop or deform for example.

In an embodiment, defects, impurities or ions are mixed with the dielectric material forming the dielectric layer before or during formation of the dielectric film on the substrate. The defects, impurities or ions may be added for example during a deposition process for forming the dielectric film on the substrate. In embodiments of this type, annealing (e.g. at a temperature above 150° C.) and application of an electric field can cause movement or rearrangement of the defects, impurities or ions to generate the required region of net charge in the dielectric film. This electric field driven movement or rearrangement of defects, impurities or ions may be referred to as “activation” of the defects, impurities or ions.

In an embodiment, the region of net charge arises due to the separation of charged entities from each other. The charged entities may be cations and anions for example. The cations and anions may be separated from each other because of different drift or diffusion speeds and/or directions (i.e. in an applied electric field anions will be driven one way and cations the other) through the dielectric film for example. In some embodiments the overall charge of the film remains neutral despite the charge separation. In other embodiments the separation of charge causes the dielectric film to develop a net overall charge. This might occur where the charge separation involves the migration of one charged species into the bulk of the film, with an oppositely charged species remaining at or near the surface (and thus vulnerable to being lost to the environment above the film).

In an embodiment, the method comprises depositing a substance containing cations and anions on the surface of the dielectric film, prior to or during the dielectric film being at a temperature greater than 150° C., the region of net charge being generated by diffusion of the cations away from the anions. In such an embodiment, the cations or anions may be chosen so that they diffuse at different speeds to each other and naturally separate during the diffusion process.

Impurities or ions which are applied to the dielectric may take a wide variety of forms. The key characteristic is that they can be made to cause a local electric field to develop that penetrates into the substrate and which is stable over time at operating temperatures of the device using the substrate unit (typically at room temperature or higher). The impurities or ions may be dielectric or metallic. Ionic species are not necessarily of anion-cation nature, but can also be charged metallic ions—i.e. cations alone, such as Au, Cu, La, Al, Pt, B, and many others.

In an embodiment, the region of net charge is generated or redistributed by depositing ions formed by a corona discharge on the dielectric film. The corona discharge may be generated in a region of space that is directly adjacent to the film or may be generated remotely and a flow of gas (e.g. air) used to carry the ions from the region of generation to the surface of the film. In an embodiment, the ions are generated remotely in a region that is at room temperature and conveyed to the film while the film is at a temperature above 150° C., optionally while the film is within an enclosed space (e.g. a furnace) that is at a temperature above 150° C. This approach obviates the need for any or all of the apparatus elements necessary for generating the corona discharge to be in the higher temperature region.

The use of a remote corona discharge also makes it easier to control the build up of the potential difference across the dielectric than arrangements in which the corona is created in a region directly adjacent to the film. In the absence of such control, there is a risk that the film itself could undergo a degree of electrical breakdown. This could have two effects. Firstly, the substrate underneath could be damaged, resulting in recombination sites that reduce the intended beneficial effect of the ions. Secondly, the dielectric film may become more leaky, leading to less efficient storage of the regions of net charge, thus reducing the longevity of the beneficial effect of the ions.

In an embodiment, two corona discharges are provided, both remote from the dielectric film and of opposite polarity to each other. The ions produced by each are conveyed towards the dielectric film by flows of gas and mixed prior to reaching the dielectric film. An electric field is then applied to drive one of the two sets of ions into the film to establish the internal electric field. The mixing of the ions in the region above the film makes it possible to reduce further to risk of any breakdown in the dielectric film itself.

Preferably, the step of generating the regions of net charge within the dielectric is performed while the dielectric film is at a temperature in the range of 150-800° C., more preferably in the range of 350-800° C., even more preferably in the range of 400-600° C.

By dielectric “film”, what is meant is a surface layer having a thickness of less than 50 micron.

By “dielectric”, what is meant is a material having an electrical resistivity of more than 1e8 Ohm·cm, optionally more than 1e9 Ohm·cm.

Reference is made throughout to applying “impurities” or “ions” to the dielectric. The impurities may be charged (ions) or uncharged (atoms or molecules) or a mixture of both, both before and after migration into the bulk of the dielectric. In some cases, the impurities may be charged or uncharged when lying on the surface of the dielectric film but when the impurities enter the bulk of the dielectric film (due to thermal diffusion or drift or a mixture of both), a significant proportion of the impurities will be charged themselves and/or will produce a region of net charge in the bulk of the dielectric by other means (for example by affecting the surrounding dielectric in such a way as to induce a region of net charge). The impurities or ions referred to thus cover any particles which have the effect of inducing a region of net charge within the dielectric.

A “region of net charge” is a region of any shape within the dielectric where there is an overall imbalance of charge. This may arise where a dipole is present and the region is defined so as not to surround the whole dipole. The region of net charge is such as to produce an electric field in the dielectric which penetrates into the substrate adjacent to the dielectric.

According to an alternative aspect of the invention, there is provided a substrate unit manufacturing device, comprising: a charging unit for generating or redistributing a region of net charge within the dielectric layer while the dielectric layer is at a temperature greater than 150° C.

In an embodiment, the substrate unit is used in a semiconductor detector (e.g. an optical sensor in an optical camera). The substrate unit according to embodiments of the invention is particularly effective in this context where improved performance in the UV range is required. The dielectric film in such embodiments may comprise one or more dielectric antireflection coatings. The antireflection coatings may comprise one or more of many different materials. Some example materials are disclosed in U.S. Pat. No. 6,967,771 B2 for example. Common materials include magnesium fluoride, titanium oxide and hafnium oxide, but there are many others. An electric field to keep one type of carrier away from the interface between the substrate and the dielectric film is important to obtain good passivation properties for this interface. This can be achieved two ways. The first is by introducing charge into the dielectric film (which is the approach adopted by embodiments of the present invention). The second is by introducing an electric field into the semiconductor itself. This is the approach adopted by the better performing existing optical sensors in this area. The electric field is introduced into the semiconductor by forming a very highly doped, thin surface layer in the semiconductor substrate. The Fermi level is flat so the bands bend, which provides the electric field. However, the highly doped surface material has degraded properties compared to the bulk because Auger recombination is speeded up here, locally reducing carrier lifetime. Now, although this layer is thin, UV is absorbed very close to the surface and so this recombination in the highly doped material has a particularly large effect on the UV portion of the spectrum. With the processing of embodiments of the present invention no highly doped layer is required to get the same or better degree of surface passivation.

Embodiments of the invention will now be described, by way of example only, with reference to the accompanying drawings in which corresponding reference symbols indicate corresponding parts, and in which:

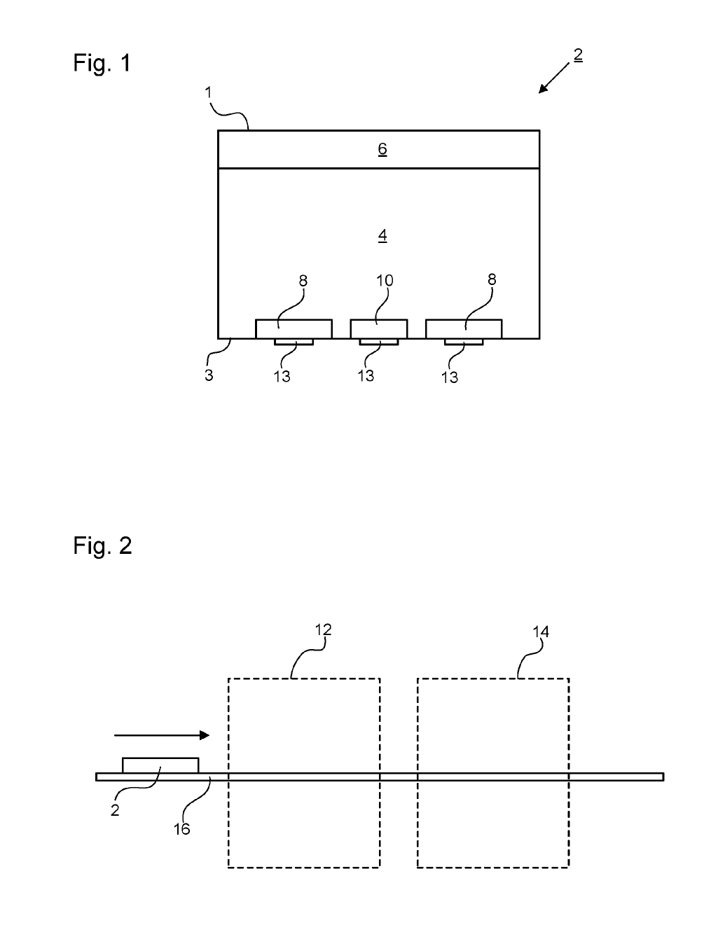

FIG. 1 depicts a solar cell comprising a substrate unit manufactured according to a disclosed embodiment;

FIG. 2 depicts a substrate unit manufacturing device comprising a dielectric film forming unit and a charging unit;

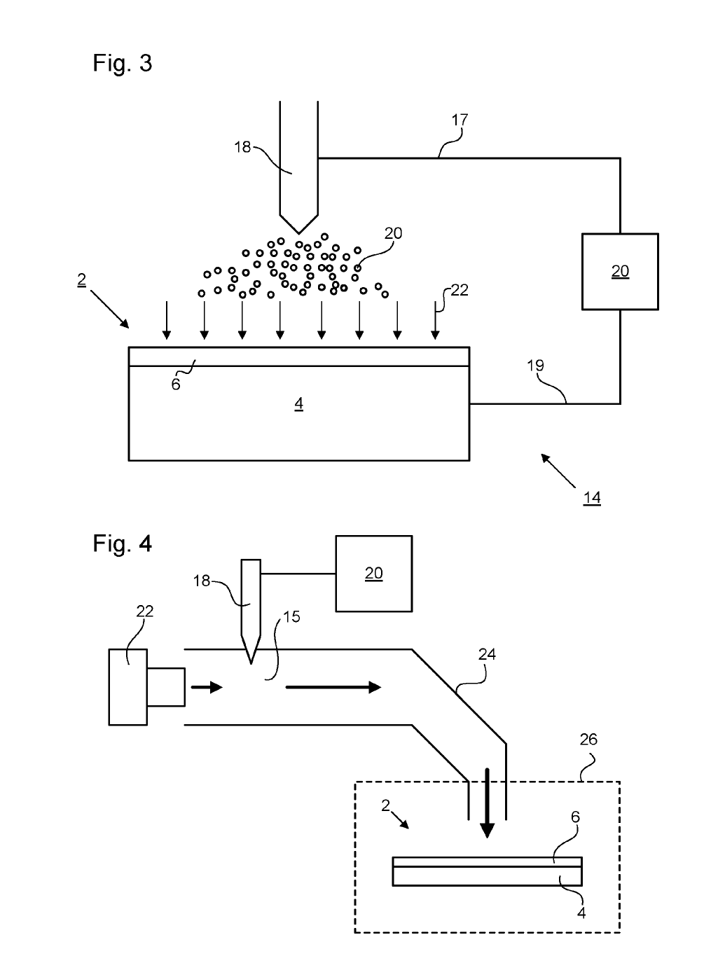

FIG. 3 depicts a charging unit for generating a net charge within the dielectric film of a substrate unit;

FIG. 4 depicts a substrate unit manufacturing device configured to generate ions remotely using a corona discharge and convey the ions to the dielectric film using a flow of gas;

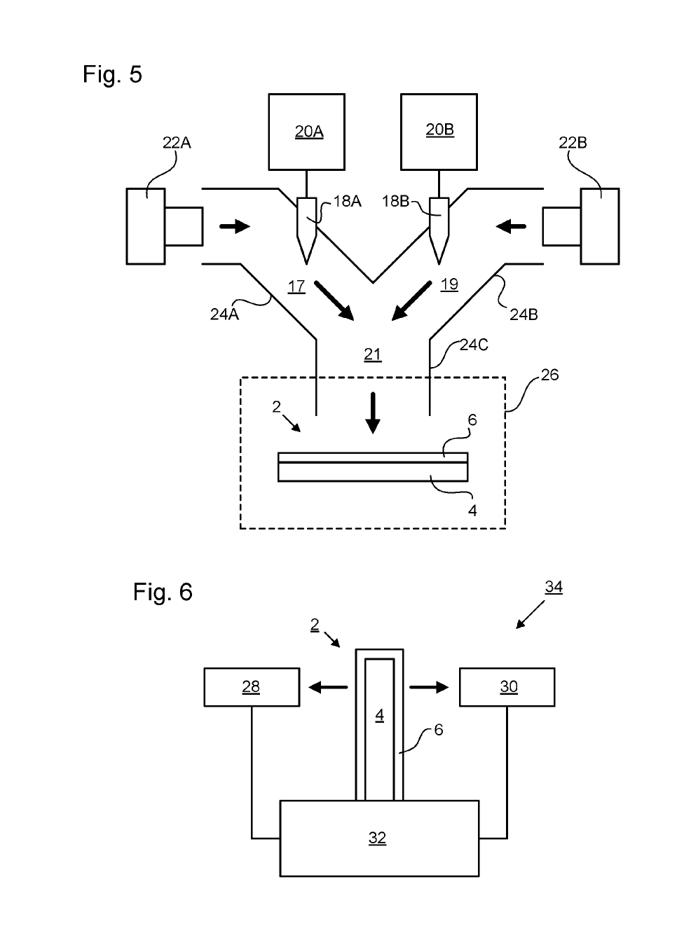

FIG. 5 depicts a substrate unit manufacturing device configured to generate two corona discharges of opposite polarity and to mix flows of gas comprising the ions of opposite polarity in a region upstream of the film;

FIG. 6 depicts an electrostatic film comprising a substrate unit according to an embodiment;

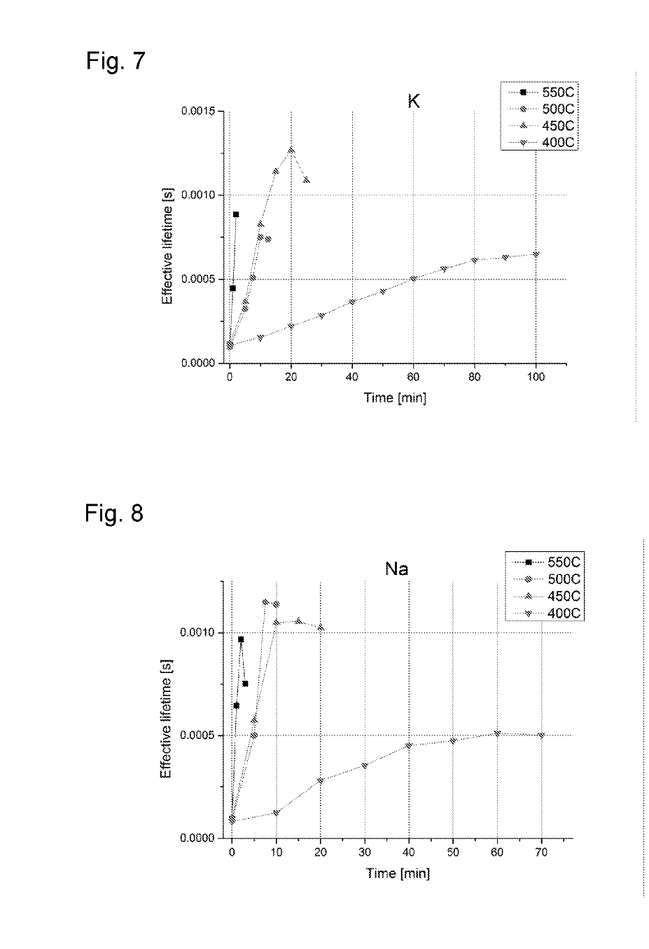

FIG. 7 is a graph illustrating the effect of K ions on carrier lifetimes for different annealing temperatures and times;

FIG. 8 is a graph illustrating the effect of Na ions on carrier lifetimes for different annealing temperatures and times;

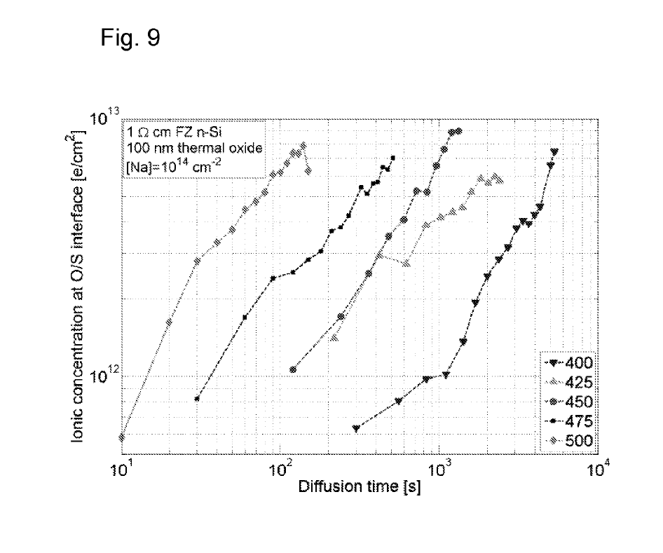

FIG. 9 depicts experimental results from a first example configuration in which sodium ions are made to diffuse into a silicon dioxide dielectric film;

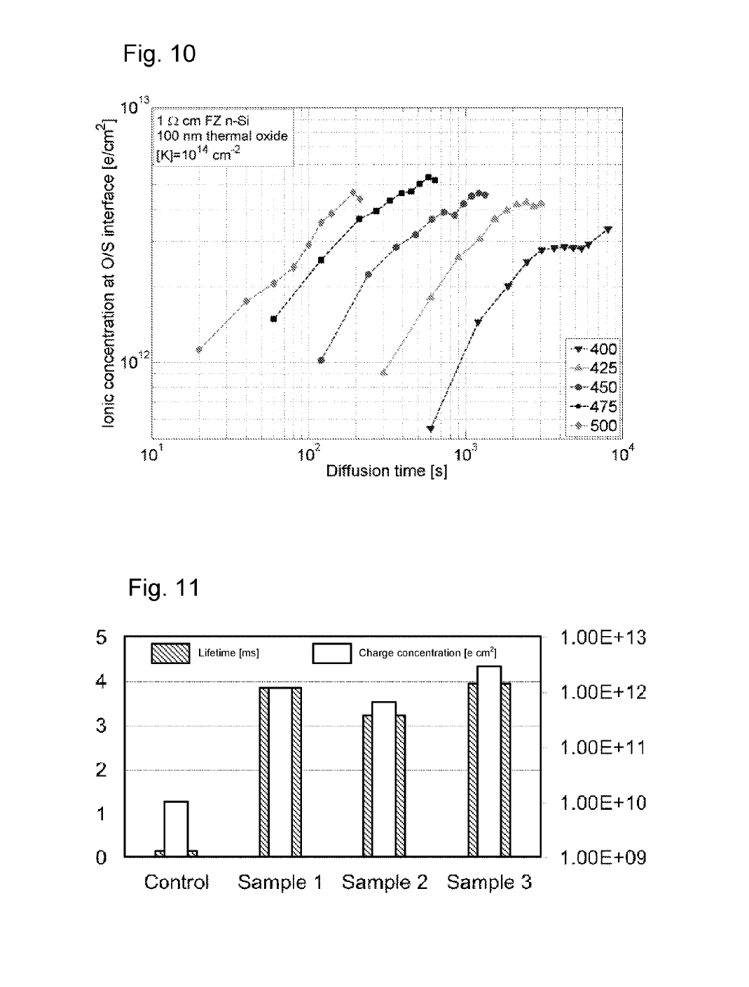

FIG. 10 depicts experimental results from the first example configuration in which potassium ions are made to diffuse into a silicon dioxide dielectric film;

FIG. 11 depicts experimental results from a second example configuration in which aluminium is made to diffuse into a silicon dioxide dielectric film;

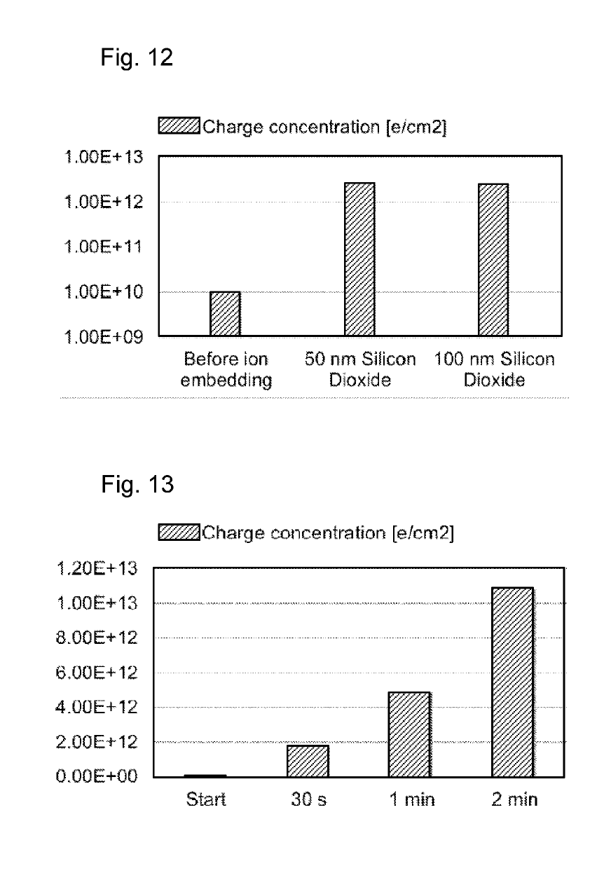

FIG. 12 depicts experimental results from a third example configuration in which aluminium is made to move rapidly into a silicon dioxide dielectric film using an externally applied field;

FIG. 13 depicts experimental results from a fourth example configuration in which gold is made to move rapidly into a silicon dioxide dielectric film using an externally applied field; and

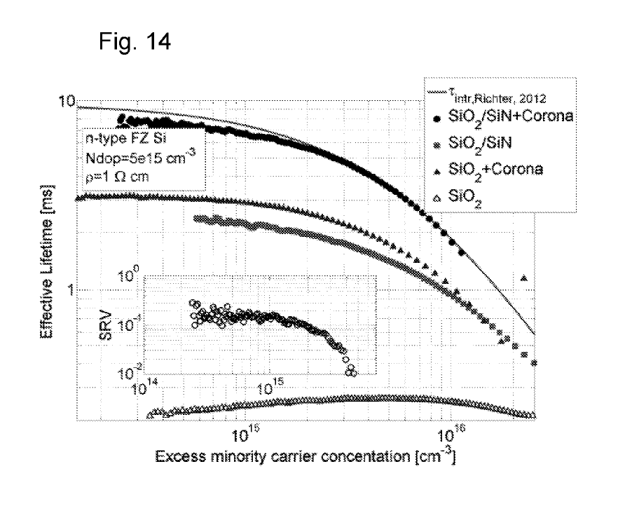

FIG. 14 depicts experimental results from a fifth example configuration showing how field effect passivation leads to very high passivation quality.

In the following, “electronic device” is intended to cover any device that operates based on electromagnetic principles, including solar cells, semiconductor sensors, electrostatic actuator, and many other devices.

Recombination of electrical charge carriers at the surfaces/interfaces of semiconductors can be an important issue in many applications. Recombination tends to be higher near surfaces/interfaces because these act as “defects” in the material and are generally associated with electronic states in the forbidden band gap—“surface states”. These states allow rapid recombination of electrons and holes when both carrier types are present at the surface/interface, and so reduce the carrier concentration and lifetime. Thus, any practical application which depends on long carrier lifetimes or high carrier concentrations can be adversely affected by surface recombination mediated by these surface states.

Such carrier recombination is important in electronic devices such as solar cells and semiconductor detectors, and in electrostatic actuators, sensors, harvesters or other electro-mechanical devices, for example.

For a silicon solar cell, for example, at the back surface (i.e. the surface opposite to the surface facing the incoming light) it is usual to make an ohmic contact using an Al layer. This contact coincidentally generates an internal electric field which serves to repel electrons from this surface and so reduces the overall recombination at the back surface. However, the front surface also represents a problem, particularly in back contact geometries where both the ohmic and pn-junctions are formed at the back surface and recombination of carriers at the front surface can markedly reduce the flux of carriers to the back surface where the photo-current is collected.

FIG. 1 is a schematic illustration of a substrate unit 2 according to an embodiment. In this embodiment, the substrate unit 2 comprises a silicon substrate and is configured for use in a silicon solar cell having a back contact geometry. The substrate unit 2 comprises a dielectric film 6, which acts as an antireflection coating, and a silicon substrate 4. In the example shown, the silicon substrate 4 is doped so as to be n-type, and p-type contacts 8 are provided on the rear surface to form pn-junctions. An ohmic contact, formed using an n+ diffused layer 10, is positioned between the two p-type contacts 8. Metallisation layers 13 may be provided on the n+ diffused layer 10 and/or on the p-type contacts 8.

In alternative embodiments, the ohmic contact 10 could be provided on the front surface (the surface facing incoming light).

It has been known for many years that the application of an electrostatic charge to a semiconductor surface can modify surface recombination. This is due to the generation of a surface electric field which penetrates into the semiconductor and repels either electrons or holes. Since recombination requires both to be present simultaneously at the surface, the repulsion of carriers away from the surface reduces surface recombination. The reduction of surface recombination is often termed “surface passivation”.

Although of academic interest, surface passivation of this type has not been used commercially (e.g. for solar cells) because the effect (when carried out at room temperature) is only temporary and the surface charge gradually disappears (or can either be wiped or washed off). This is not appropriate for commercial applications. For example, in solar cells it would be desirable for the surface passivation effects to last for many years.

In the present work, it has been realised that the surface passivation effect can be made to last much longer if the establishment of a region of net charge in the dielectric film of a substrate unit (such as to cause a localized electric field to penetrate into the substrate) is carried out while the dielectric film is hot, for example at a temperature higher than 150° C., more preferably in the range 350-800° C., or more preferably in the range 400-600° C. (either by applying charges at low temperature and heating the dielectric film at a subsequent time, before the charges disappear, or by applying charges while the dielectric film is hot). At high temperature, the defects, impurities or ions associated with the net charge generated in the dielectric film 6 can migrate deep enough into the bulk of the dielectric film 6 that they will effectively be “frozen” into the dielectric film after the dielectric film has been cooled. In contrast to the situation where the regions of net charge are generated at room temperature, a net charge generated at these higher temperatures cannot easily be wiped or washed off and will tend to remain within the dielectric film for an extended period of time, typically many months or even years.

FIG. 2 illustrates a substrate unit manufacturing device comprising a dielectric film forming unit 12 and a charging unit 14 for generating a region of net charge within the dielectric film while the dielectric film is at an elevated temperature. Transport means 16 are provided for transferring the substrate unit 2 to the dielectric film forming unit 12, where the dielectric film is formed on the substrate, and for transferring the substrate unit 2 from the dielectric film forming unit 12 to the charging unit 14. In the example arrangement shown, the dielectric film forming unit 12 and the charging unit 14 are shown as units spatially separated from each other, so that the substrate unit 2 needs to be moved from one to the other. However, this need not be the case. For example, the substrate unit manufacturing device may be configured such that the substrate unit 2 remains in the same position while the dielectric film is formed on the substrate and the net charge is generated in the dielectric film. In any event, it is preferable that the substrate unit manufacturing device is configured such that the temperature of the dielectric film, once formed on the substrate does not fall below 150° C. between the step of forming the dielectric film and the step of establishing the region of net charge in the dielectric film. In other words, it is preferable that the manufacturing process take advantage of the fact that both the step of forming the dielectric film and the step of establishing the net charge within the dielectric film both require an elevated temperature. This approach is more efficient than the alternative of generating the dielectric film in a first high temperature process, allowing the substrate unit to cool (to below 150° C.), and then heating the substrate unit up again in order to generate the net charge within the dielectric film at an elevated temperature in a second high temperature process.

FIG. 3 illustrates a schematic configuration for a charging unit for generating a net charge within the dielectric film while the dielectric film is at a temperature greater than 150° C. The means by which the elevated temperature is generated are not depicted in FIG. 3, but it would be clear to the skilled person how this could be achieved, for example by locating some or all of the components depicted within a suitable furnace.

The charging unit 14 according to the example shown in FIG. 3 comprises a high voltage source 20 configured to apply a voltage between the substrate unit 2 (via a connection to the substrate 4, and/or dielectric film 6) and a connection to an electrode 18. The voltage applied and the geometry of the electrode 18 are controlled in order that a corona discharge be generated in the region adjacent to the dielectric film 6. The corona discharge causes a net charge to be deposited on the surface of the dielectric film 6. The elevated temperature encourages migration of charged ions associated with the net charge into the bulk of the dielectric film 6, as described above. This process can be accelerated by applying an external electric field to the dielectric film 6. In the example shown, the electrical connections from the high voltage source 20 for producing the corona discharge produce such an electric field, but alternative or additional arrangements may be provided. The field provided by the corona discharge may also be effective to cause migration of ions already present on the film (i.e. ions not produced by the corona discharge) into the bulk of the dielectric, as well as activation of ions already present in the bulk of the dielectric by causing them to move and produce a localized electric field.

The sign of the charge that is deposited on the dielectric film 6 will depend on the polarity of the potential difference applied by the high voltage source 20. A “positive” corona discharge can be generated if the potential difference is such as to cause the electrode 18 to repel positive charges. In this case, the net charge generated in the dielectric film 6 will be positive. A “negative” corona discharge is the opposite.

The optimal temperature to choose for the process of generating the net charge within the dielectric film 6 will in general depend on a variety of factors. However, it is expected that a relatively wide range of temperatures will achieve satisfactory results. Generally, it is expected that at lower temperatures (for example temperatures near 150° C.), the process of migration of the charged ions into the bulk of the dielectric film 6 will be relatively slow. In contrast, at higher temperatures (for example temperatures nearer to 800° C.), it is expected that migration of the charged ions into the bulk of the dielectric film 6 may occur relatively quickly, but care will need to be taken when using such high temperatures that the cooling takes place sufficiently quickly that the charged ions, which will be more mobile at higher temperatures, do not escape during cooling. The extent to which net charge may be lost in this way can be mitigated by maintaining the corona discharge during cooling. Alternatively, if it is more practical to allow the substrate unit 2 to cool after the corona discharge has finished, it will be necessary to select an appropriately rapid cooling regime and/or select a lower initial temperature.

For temperatures in the range of 150-800° C., it is expected that the charges deposited by the corona discharge will migrate to a sufficient extent into the bulk of the dielectric film 6 within a time scale of the order of a few minutes or less. Such short time scales should allow the additional processing proposed in this work to be incorporated efficiently into existing production lines for substrate units with a minimum of disruption to efficiency.

Examples of dielectric films which may be used in the context of the present invention include oxides, hydrides, carbides, fluorides, and nitrides of metals such as aluminium, titanium, hafnium, cerium, silicon, boron, tantalum, magnesium, and others, including for example silicon nitride, titanium oxide, silicon dioxide, silicon oxynitride, and aluminium oxide. The dielectric film may comprise a single layer having a uniform composition or multiple layers (at least two of the layers having different compositions relative to each other). The composition of the film or the multiple films may be chosen so as to achieve a desirable combination of good chemical passivation at the substrate and good electrostatic charge retention and stability.

The above-described reduction in carrier recombination achieved through the application of corona discharges at high temperature does not depend on the nature of the dielectric. This fact, together with the effectiveness of the net charge in the dielectric film in reducing recombination, relative to the passivation effects achievable purely by selecting dielectric films with good electronic passivation properties, significantly increases the freedom for selecting a material for the dielectric film. This allows the material of the dielectric film to be chosen so as to favour other factors. For example, in the case of solar cells or detectors, a balance between optimal optical properties and optimal electronic properties of the dielectric film can be biased further towards optical properties.

In the above embodiments, a corona discharge is created in a region immediately adjacent to the surface of the dielectric film. However this is not essential. In other embodiments, the corona discharge may be generated remotely. For example, the corona discharge may be generated in a region of space that is separated from the film 6 be one or more apparatus elements (e.g. the walls of a channel) and/or by a region of gas that is not affected by the corona discharge.

In an embodiment, the ions generated by the remote corona discharge are conveyed to the dielectric film 6 by entraining them in a flow of gas. An example of an apparatus for carrying out such a process is depicted in FIG. 4.

When the corona discharge is generated in the region directly adjacent to the film, a large potential can develop at the surface of the film 6. One approach for example is to use a “point to plane” (point shaped electrode and planar film) configuration with the discharge taking place at the point. However, potentials of several kV are typically required to generate the corona in such a configuration and as the ions flow through the air they make it electrically conducting. This causes the potential of the surface of the film 6 to be driven towards that of the electrode. This can cause a large potential difference to develop across the film 6 which can cause electrical breakdown of the film. As discussed above in the introductory part of the description, the damage to the film can introduce defects which act as carrier recombination centres and/or can cause the film 6 to become leaky.

Creating the corona discharge remotely and conveying the generated ions to the surface of the film 6 allows the build up of potential on the film 6 to be controlled more easily and thus helps to avoid or reduce the extent of any electrical breakdown of the film 6.

In the embodiment of FIG. 4, an electrode 18 and high voltage source 20 are configured to provide a corona discharge in a region 15 that is remote from the dielectric film 6. A gas source 22 provides a flow of gas through the region 15. A channelling system, in this embodiment comprising a channel 24, directs the flow of gas from the region 15 to the surface of the dielectric film 6. The flow is indicated schematically by the thick line arrows. The flow entrains ions produced in the region 15 by the corona discharge to the dielectric film 6. Thus, ions can be deposited on the surface of the film 6 without developing a large potential on the surface of the film in an uncontrolled manner. The risk and/or extent of breakdown of the film is therefore reduced.

In an alternative embodiment, corona discharges of opposite polarity are generated remotely with the positive and negative ions being conveyed together to the film 6. In this way, the charge initially deposited on the surface of the film is more (or completely) balanced, which results in a smaller build up of potential on the surface of the film 6 and a lower chance of electrical breakdown of the film. Furthermore, where the ions are mixed in the region adjacent to the film 6 approximate neutrality is achieved in this region which reduces the space charge effects that appear when only one species is present. An example of an apparatus for performing such a process is depicted in FIG. 5. In an embodiment, the ions are deposited at room temperature in a first stage and then annealed in a second stage to drive one of the sets of ions into the bulk of the film to create the desired polarisation. The annealing step may be performed under an external electric field or, alternatively, the electric field associated with the ions themselves may be adequate to cause the driving of the ions into the bulk.

In the embodiment of FIG. 5, a first gas source 22A is provided for supplying a first flow of gas. A first corona discharge generation device (comprising in this embodiment an electrode 18A and high voltage source 20A) is provided for generating a first corona discharge in a region 17 downstream from the first gas source 22A. A first channelling system (in this embodiment comprising a channel 24A) is provided for directing the first flow of gas through the region 17 containing ions generated by the first corona discharge and towards the film 6. A second gas source 22B is provided for supplying a second flow of gas. A second corona discharge generation device (comprising in this embodiment an electrode 18B and high voltage source 20B) is provided for generating a second corona discharge in a region 19 downstream from the second gas source 22B. The second corona discharge is opposite in sign to the first corona discharge so the ions generated thereby have the opposite polarity to the ions generated by the first corona discharge. A second channelling system (in this embodiment comprising a channel 24B) is provided for directing the second flow of gas through the region 19 containing ions generated by the second corona discharge and towards the film 6.

In the embodiment shown, the first and second channelling systems are configured to cause the ions from the two different corona discharges to mix in a region 21 upstream of the film. In the particular embodiment shown, this is achieved by arranging for the channels 24A and 24B of the first and second channelling systems to join together to form a single channel 24C leading to the film 6. Gas and ions from each of the two channels 24A and 24B can thus mix in the channel 24C. The channel 24C may be considered to be shared by the first and second channelling systems (i.e. a part of both).

In other embodiments, the flows of ions from the different corona discharges are channelled separately to the surface of the film and do not mix significantly in a region upstream of the film. In the embodiment shown in FIG. 5, the high voltages sources 20A and 20B are shown as separate devices but this is not essential. In other embodiments, a single device is configured to apply the necessary voltages to both of the two electrodes 18A and 18B.

In an embodiment, the apparatus is configured such that the corona discharge or, where applicable, discharges (e.g. for embodiments of the type illustrated in FIG. 5), are performed at room temperature (e.g. in the region of 25° C.) and the channelling system or systems is/are configured to channel the ions produced to a region that is at a temperature greater than 150° C. and containing the substrate unit 2. This is the case for example in the embodiments of FIGS. 4 and 5, wherein the region 26 delimited by broken lines indicates a region that is at a temperature greater than 150° C. The region 26 may correspond to the interior of a furnace, for example. Thus, in this approach, apparatus that is involved in creating the corona discharge (e.g. high voltage source(s) and/or electrode(s)), as well as apparatus involved with creating and directing gas flows (e.g. gas source(s) and/or channelling system(s)), can be located in room temperature regions and do not therefore need to be specially configured so as to be able to operate at high temperatures. Avoiding the need for such special configuration simplifies device construction and reduces cost. Furthermore, control, maintenance and general access to apparatus elements is facilitated when the apparatus can be held at room temperature. At the same time, the provision of means to convey ions to the substrate unit 2 which is held at high temperature allows the ions to migrate into the dielectric film as desired. In an alternative embodiment the substrate unit 2 may also receive the ions while at room temperature and be heated at a later time to allow migration of the ions into the bulk of the dielectric.

In the above embodiments, a region of net charge is generated in the film 6 by depositing ions generated by a corona discharge on the surface of the film 6 and allowing the ions to diffuse into the film or applying an external electric field to drive the ions into the film 6. However, this is not essential. In other embodiments of the invention, the region of net charge may be generated differently, for example by polarisation of the film 6, for example using defects and/or impurities present in the film 6.

If there are defects in the film which are (or can be) charged then under the application of an electric field whilst hot they will tend to rearrange themselves giving rise a to a net electric dipole within the dielectric. This could be either by macroscopic movement under the action of the applied field (drift) of charged impurities in the film or by an atomic scale rearrangement of the defects present. As described earlier, such charged impurities may be introduced deliberately into the dielectric film during formation of the dielectric film on the substrate. The impurities may move some distance within the film or may drift all the way to the interface between the substrate 4 and dielectric film 6 and then remain at this interface.

The impurities and/or defects may be present in the film 6 as originally formed. Alternatively or additionally, defects, impurities or ions may be deliberately added to the surface of the film to create or enhance the desired generation of a region of net charge (e.g. via polarisation). The defects, impurities or ions may drift into the film 6 under the action of an externally applied electric field and/or may be allowed to diffuse into the film 6.

The inventors have found that, for example, a suitable deposition of KCl or NaCl can be achieved using the following method. A very dilute solution of these ions is prepared and loaded onto a thermal or electron beam evaporator target. The solution is then allowed to dry. This means that the target is “loaded” with a known amount of material. The material is then evaporated from the target using the thermal or electron beam evaporator so as to deposit a known amount of the material on the surface of the dielectric layer. This processing may then be followed by annealing under an applied electric field (e.g. 1 MV/cm directed into the dielectric). The K or Na then drifts quickly into the film and creates the desired region of net charge. The Cl remains near the surface and/or escapes from the film 6. FIGS. 7 and 8 illustrate the results of experiments of this type carried out by the inventors that illustrate the effectiveness of K and Na, respectively, in reducing carrier recombination. The vertical axes in FIGS. 7 and 8 measure effective lifetime of carrier in seconds. Recombination reduces carrier lifetimes so higher values indicate reduced recombination. The horizontal axes represent anneal time in minutes. As can be seen, at the lowest annealing temperature of 400° C. the carrier lifetime increases steadily with time but would take several hours to reach a peak value. At higher temperatures the increase of carrier lifetime happens much more quickly. At 550° C. the carrier lifetime rises to, or near to, a peak value within about a minute. These experiments also illustrate the extent of improvement that is necessary. In both cases, the carrier lifetime is seen to rise by a factor of 12 due to the region of net charge that has been introduced into the bulk of the dielectric film by the deposition and annealing processes. Further experimental data showing in-diffusion of Na and K is discussed below within reference to FIGS. 9 and 10 (“Example 1”).

The inventors have also found that when KCl, NaCl, KOH, NaOH CsOH etc ions are present on the surface of the film 6 and it is then heated, the cations preferentially dissolve into the dielectric resulting in charge imbalance and consequently an electric field. This process occurs much slower than when an external electric field is also present (drift of ions is generally faster than their diffusion) but may still be useful.

In an embodiment one or more of the following ions are deposited on the film 6 and annealed under an applied electric field: Sodium, Potassium, Rubidium, Caesium, Magnesium, Calcium, Gold, Copper, Lanthanum, Aluminium, Platinum, and Boron.

In the case where defects, impurities or ions are deposited on the film it is generally desirable to apply an external electric field to ensure that the defects, impurities or ions drift into the bulk of the dielectric at a rapid rate. In an embodiment, impurities or ions are applied to the dielectric film at a concentration which is such as to reduce the transmittance of the dielectric film by less than 5%, optionally less than 1%, optionally less than 0.1%. For example, in an embodiment the impurities or ions are applied at three times a monolayer concentration or less, optionally at a monolayer concentration or less, optionally at a sub-monolayer concentration. For example, a concentration of impurity/ion particles of the order of 1 particle to 100 molecules of the dielectric film may be used. The inventors have recognised that even such low concentrations of impurity/ion particles can be adequate to achieve high levels of passivation. Where the substrate unit needs to be transparent (e.g. in solar cells) this approach facilitates manufacture, relative to alternative approaches in which thicker layer of impurities or ions are used, because it is no longer necessary to incorporate an extra step of removing the layer of impurities or ions after the required region of net charge has been generated in the dielectric film by diffusion and/or drift of the impurities or ions.

In an embodiment, an HMDS layer is applied to the film 6 after the film 6 has been processed to introduce the region of net charge. HMDS produces a monolayer coating which is highly hydrophobic and will reduce any potential impact of water on the films containing the electric field.

The substrate unit may be used in various electronic devices. For example, the substrate unit may be used in a solar cell. Here, the passivation effect achieved at the interface between the substrate and the dielectric film improves efficiency. In a further example, the substrate unit is used in a semiconductor detector. Here, the passivation effect achieved at the interface between the substrate and the dielectric film improves sensitivity. In a further example, the substrate unit is used in an electrostatic actuator, for example as part of a so-called Micro-Electro-Mechanical System (MEMS). Here, the region of net charge generated in the film 6 can be used to mediate the electrostatic actuation mechanism. An example of such a device is illustrated schematically in FIG. 6.

In the embodiment of FIG. 6, a MEMS 34 (or portion thereof) comprises a substrate unit 2 according to an embodiment. The substrate unit 2 comprise a substrate 4 and a dielectric film 6 comprising a region of net charge (imparted for example according to one of the methods discussed above). In an embodiment, the substrate unit 2 is constructed so as to act as an actuatable member (e.g. a member that can be deformed or displaced when a force is applied to the member or to part of the member). In the embodiment shown, a force can be applied via electrodes 28 and 30, which are controlled by control unit 32. For example, the control unit 32 may be configured to generate a potential difference between the electrodes 28 and 30 so as to generate an electric field in the region between the electrodes 28,30. The electric field couples with a region of net charge stored in the film 6 in the region between the electrodes and allows selective application of a force to the distal end of the substrate unit 2. The force can thus be used to deflect the tip of the substrate unit selectively to the left or right as desired.

The dielectric film 6 and substrate 4 may be connected together as a unit before application of the processing of annealing under electric field is performed. In such embodiments, the annealing and electric field are not suitable or intended to perform any bonding process.

In embodiments where the substrate unit is applied to an electronic device in which the substrate is involved actively in an electronic process (e.g. in a solar cell or semiconductor detector), the dielectric film 6 may be configured (e.g. formed from a material having a large enough energy band gap) that it does not contribute to the electronic performance of the device. However, the dielectric layer may act as an anti-reflection coating and/or passivation layer.

Five specific, non-limiting examples and experimental data are now discussed.

### EXAMPLE 1

### In-Diffusion of Sodium and Potassium Ions into Silicon Dioxide

FIGS. 9 and 10 respectively show concentrations of sodium and potassium ions migrated to the substrate-dielectric interface (oxide-silicon, “O/S”, interface in this example) of a substrate unit of an embodiment as a function of anneal time for a range of temperatures and times.

The substrates of the substrate units were n-type FZ silicon doped with 5e15 P atoms per cm³. The substrates were then oxidized in a dry environment at 1050° C. to grow 100 nm thick dielectric film consisting of SiO₂ film. NaCl (FIG. 9) and KCl (FIG. 10) were then deposited with 1e14 NaCl/KCl atoms per cm² and diffused at the temperatures marked in the legends in the lower right hand corners of the graphs of FIGS. 9 and 10 (which indicate temperatures in degrees Celsius). It can be seen that diffusion times for achieving a given ionic concentration at the O/S interface fall rapidly with increasing temperature. It can also be seen that very short diffusion times are achieved for the higher temperatures, facilitating efficient manufacturing of devices based on this process.

### EXAMPLE 2

### In-Diffusion of Aluminium into Silicon Dioxide

FIG. 11 shows the effect of in-diffusion of aluminium into a dielectric film consisting of silicon dioxide. The carrier lifetime and charge concentration for a control substrate unit and for three substrate unit “samples” which have undergone the in-diffusion of aluminium are shown. The substrate in each case was n-type silicon doped with 5e15 P atoms per cm³. The substrate was oxidised in a dry environment at 1050° C. to grow 100 nm thick SiO², which acted as the dielectric film of the substrate unit. Apart from the control substrate unit, the substrate units were then deposited with 15 nm layer of aluminium and submitted to a 425° C. anneal in argon for 30 minutes. After removing the aluminium, the lifetime was increased to >3 ms levels indicating field effect passivation. This was corroborated by capacitance-voltage measurements that showed a high charge concentration inside the film.

### EXAMPLE 3

### Rapid Embedding of Aluminium into Silicon Dioxide Using Electric Field Driven Drift

FIG. 12 shows how aluminium can be embedded much more quickly than by diffusion alone using an externally applied electric field (e.g. from a corona discharge). Substrate units comprising substrates of n-type silicon doped with 1e14 P atoms per cm³ were used. The substrates were oxidised in a dry environment at 1000° C. to grow either a 50 nm (middle bar) or 100 nm (right-hand bar) thick SiO₂ film, which acted as the dielectric film of the substrate unit. Apart from the control substrate unit (left-hand bar), these were then deposited with ˜100 nm layer of Al and submitted to a hot corona discharge for 1 minute at ˜430° C. Capacitance voltage measurements of the voltage shift indicate that charge has been embedded in the film using a diffusion plus drift process.

Comparing the behaviour of Example 3 with the behaviour of Example 2, it was seen that a charge concentration which required a 30 minute anneal in the configuration of Example 2 (without an externally applied field) can be produced in one minute in the configuration of Example 3 (with an externally applied field).

### EXAMPLE 4

### Rapid Embedding of Gold into Silicon Dioxide Using Electric Field Driven Drift

FIG. 13 shows the performance of a configuration that is similar to that of Example 3 except that gold is used instead of aluminium. The substrate was n-type silicon doped with 5e14 P atoms per cm³. The substrate was oxidised in a dry environment at 1000° C. to grow 97.5 nm thick SiO₂, which acted as the dielectric film of the substrate unit. A layer of gold of ˜7 nm thickness was then deposited on the dielectric film and submitted to a hot corona discharge for different time intervals (30 s, 1 min and 2 min) at 400° C. Capacitance voltage measurements of the voltage shift indicated that charge had been embedded in the film using a diffusion plus drift process.

Again, it can be seen that a rapid increase in charge concentration is seen in less than one minute and a high charge concentration is achieved within only 2 minutes.

### EXAMPLE 5

### Very Low Effective Surface Recombination Velocity for a Passivation Double Layer

The fifth example demonstrates how the field effect passivation according to an embodiment is shown to lead to a very high passivation quality in a substrate unit comprising a silicon substrate and a double layer dielectric.

The substrate unit tested in this example was processed as follows. An n-type silicon substrate was doped with 5e15 P atoms per cm³ was oxidized in a dry environment at 1050° C. to grow 100 nm thick SiO₂ dielectric layer. A PECVD SiN film 80 nm thick was then deposited on the SiO₂ layer to enhance chemical passivation. Finally, a corona discharge was applied to achieve field effect passivation.

The results are shown in FIG. 14. Effective lifetime (vertical axis) is plotted against excess minority carrier concentration for four different dielectric film configurations: a single SiO₂ layer with no corona discharge processing (lowest data curve); 2) a single SiO₂ layer that has been treated with a corona discharge (second data curve from top); 3) a SiO₂ layer that has had a SiN layer deposited on top (second data curve from bottom); and 4) the combination of a SiO₂ layer that has had a SiN layer formed on top and which has been subjected to a corona discharge (highest data curve). The solid line curve which is just higher than the fourth data curve indicates the most accepted theoretical limit of lifetime. These results demonstrate clearly how effective the field effect passivation (using a corona discharge in this example) can be for increasing carrier lifetime. As the inset shows, the substrate unit treated with both the chemical passivation and the field effect passivation achieved a surface recombination velocity (SRV)<0.3 cm/s in the minority carrier concentration range analysed. This is amongst the lowest observed for similarly doped material.

1. A method of manufacturing a substrate unit for an electronic device comprising a dielectric film on a substrate, the method comprising:
generating, or redistributing into the bulk of the dielectric film, a region of net charge in the dielectric film while the dielectric film is at a temperature greater than 150° C.

2. A method according to claim 1, wherein:
the substrate comprises a semiconductor and the generated or redistributed region of net charge in the dielectric film is such as create an electric field penetrating into the semiconductor:
the generating or redistributing of the region of net charge comprises applying an external electric field; and
the external electric field causes one or more of defects, impurities and ions in or on the dielectric film to move or rearrange, thereby generating or redistributing the region of net charge.

3.-4. (canceled)

5. A method according to claim 2, further comprising depositing a dielectric material on the substrate in order to form the dielectric film on the substrate, wherein the one or more of the defects, impurities or ions are added to the dielectric material before or during the depositing of the dielectric material on the substrate.

6. A method according to claim 2, comprising applying impurities or ions to the dielectric film, the external electric field causing the impurities or ions in or on the dielectric film to move, thereby generating or redistributing the region of net charge, wherein the concentration of impurities or ions applied is such as to reduce the transmittance of the dielectric film by less than 5%.

7. A method according to claim 1, comprising applying impurities or ions to the dielectric film while the dielectric film is at a temperature above 150° C.

8. A method according to claim 1, comprising depositing a substance containing cations and anions on the surface of the dielectric film,
wherein the region of net charge is generated or redistributed by applying an external electric field to cause drift of the cations away from the anions.

9.-10. (canceled)

11. A method according to claim 1, comprising depositing ions formed by a corona discharge on the dielectric film,
wherein the corona discharge is generated while the dielectric film is at a temperature greater than 150° C.

12.-13. (canceled)

14. A method according to claim 11, wherein the corona discharge is generated remotely and a flow of gas is provided for entraining the ions produced by the corona discharge to the dielectric film.

15. A method according to claim 11, wherein:
first and second corona discharges of opposite polarity are generated;
positive ions from one of the corona discharges and negative ions from the other of the corona discharges are deposited on the dielectric film; and
an electric field is applied to the dielectric film after the positive and negative ions have been deposited on the film and while the temperature of the dielectric film is at a temperature greater than 150° C.

16. A method according to claim 15, wherein the positive ions are entrained from the one corona discharge to the dielectric film in a first flow of gas and the negative ions are entrained from the other corona discharge to the dielectric film in a second flow of gas, the first and second flows of gas mixing in a region upstream of the dielectric film.

17. (canceled)

18. A method according to claim 1, further comprising forming the dielectric film at a temperature greater than 150° C. wherein the temperature is not allowed to fall below 150° C. before the step of generating or redistributing the region of net charge within the dielectric film is initiated.

19. A method according to claim 1, wherein the step of generating or redistributing a region of net charge within the dielectric film is performed while the temperature of the dielectric film is in the range of 150 to 800° C.

20. (canceled)

21. A substrate unit manufactured according to the method of claim 1.

22. A solar cell or semiconductor detector comprising a substrate unit according to claim 21,
wherein the dielectric film is an antireflection coating.

23. (canceled)

24. An electrostatic actuator comprising a substrate unit manufactured according to the method of claim 1, the actuator being configured to selectively apply an electrostatic force to the substrate unit via the generated region of net charge.

25. A substrate unit manufacturing device, comprising:
a charging unit for generating or redistributing a region of net charge within the dielectric layer while the dielectric layer is at a temperature greater than 150° C.

26. (canceled)

27. A device according to claim 25, wherein
the charging unit is configured to produce a corona discharge and the device further comprises:
a gas source for supplying a flow of gas;
a channelling system for directing the gas in use through a region containing ions produced by the corona discharge to the surface of the dielectric film.

28. A device according to claim 27, further comprising:
a first gas source for supplying a first flow of gas;
a first corona discharge generation device for generating a first corona discharge;
a first channelling system for directing the first flow of gas in use through a region containing ions generated by the first corona discharge and onto the dielectric film;
a second gas source for supplying a second flow of gas;
a second corona discharge generation device for generating a second corona discharge;
a second channelling system for directing the second flow of gas in use through a region containing ions generated by the second corona discharge and onto the dielectric film, wherein:
the first and second corona discharges are of opposite polarity.

29. A device according to claim 28, wherein:
the first and second channelling systems are configured to mix the first and second flows of gas upstream of the dielectric film.

30. A device according to claim 27 configured to generate the corona discharge or discharges at room temperature and direct the generated ions in a flow of gas to a region at a temperature higher than 150° C.

31.-32. (canceled)
